(19) United States
(12) Patent Application Publication
(10) Pub. No.: US 2004/0175893 A1
(43) Pub. Date: Sep. 9, 2004

(54) Apparatuses and methods for forming a substantially facet-free epitaxial film

(75) Inventors: Jean R. Vatus, San Jose, CA (US); Lance A. Scudder, Santa Clara, CA (US); Paul B. Comita, Menlo Park, CA (US)

Correspondence Address: PATENT COUNSEL, APPLIED MATERIALS, INC., Legal Affairs Department, P.O.BOX 450A, Santa Clara, CA, 95052, US

(73) Assignee: Applied Materials, Inc.

(21) Appl. No.: 10/384,256

(22) Filed: Mar. 7, 2003

(51) Int. Cl. H01L 21/336

(52) U.S. Cl. 438/300

(57) ABSTRACT

A method of making a substantially facet-free epitaxial film is disclosed. A substrate having predetermined regions is first provided. An epitaxial film forming process gas and a carrier gas are introduced into a reactor chamber. The epitaxial film forming process gas and the carrier have a flow ratio between 1:1 and 1:200. The epitaxial film is deposited into the predetermined regions of the substrate wherein the substrate has a temperature between about 350° C. and about 900° C. when the epitaxial film is being deposited.

### BACKGROUND OF THE INVENTION

1. FIELD OF THE INVENTION

The present invention relates to apparatus and method of forming a substantially facet-free epitaxial film.

2. DISCUSSION OF RELATED ART

Selective deposition is used in many applications of semiconductor fabrication. For example, selective epitaxial film deposition is used to form isolated regions for semiconductor devices, raised or elevated source/drain regions, heterojunctions bipolar transistors, and ultra shallow junctions, to name a few.

An epitaxial film is typically made of a semiconductor material such as silicon, germanium, silicon alloy, or germanium alloy. A common epitaxial film is epitaxial silicon. An epitaxial silicon film, or rather, regions, can be selectively formed or deposited on a substrate having patterns already incorporated therein. For example, the substrate may include patterns such as gate electrodes, spacers, oxide films, or other structures formed thereon. In one example, and as illustrated in FIG. 1, a substrate 102 is provided with a silicon oxide film 104 formed thereon. Opening windows 106 are created into the silicon oxide film 104 to expose portions of the substrate 102 where the epitaxial silicon regions are to be deposited. The opening windows 106 can be created using conventional techniques such as photolithographic techniques and anisotropic etchings. In a conventional reactor chamber, epitaxial silicon regions 108 are deposited, for example, using a chemical vapor deposition process.

Selective deposition methods used to form epitaxial film, such as the epitaxial silicon, typically causes faceting. As illustrated in FIG. 1, each of the epitaxial silicon regions 108 contains facets 110. Faceting is the formation of another growth plane at a different angle from the major surface of the epitaxial silicon regions and often, at the sides of the regions that meet the wall of the structures already formed on the substrate. For example, the facets 110 on the epitaxial silicon regions 108 are formed at the sides that meet the wall of the silicon oxide film 104.

Faceting reduces the amount of area of the major surface of the silicon epitaxial regions available for fabrication of devices. As devices are scaled to deep submicron regime, (e.g., less than about 0.12 microns) the surfaces available for fabrication of the devices are getting extremely small. Faceting not only further reduces the available surface for fabrication of the devices, but also causes other problems. For example, it is often necessary to implant ions into the epitaxial regions. Faceting causes unevenness in the surface which makes it difficult to control the implantation process including controlling the consistency of ions implantation across the epitaxial regions. Additionally, as devices are scaled smaller, all layers of the devices need to be as thin as possible. Faceting prevents the forming of thin epitaxial regions (the thinner the epitaxial region, the more the faceting) and thick epitaxial regions limits the operating voltage of the devices fabricated on these epitaxial regions. Another problem is that one needs to modify the deposition process for the epitaxial regions depending on the amount of the opening windows (exposed substrate) where the epitaxial regions are formed. Such need for modification makes it even more difficult to control consistence thickness for the epitaxial regions from one substrate or one wafer to another.

### SUMMARY OF THE INVENTION

It is desirable to be able to selectively deposit an epitaxial film that is substantially facet-free.

In one embodiment, a method of making a substantially facet-free epitaxial film is disclosed. A substrate having predetermined regions is first provided. An epitaxial film forming process gas and a carrier gas are introduced into a reactor chamber. The epitaxial film forming process gas includes at least a silicon source gas and a chlorine source gas and optionally, a dopant source gas. The epitaxial film forming process gas may also be introduced into the reactor chamber together with the carrier gas. Generally, the epitaxial film forming process gas does not include a cleaning gas that is used to clean the reactor chamber after a deposition step. The carrier gas can be a hydrogen gas, an argon gas, a nitrogen gas, a helium gas, or other suitable dilution gas. The epitaxial film forming process gas and the carrier have a flow ratio between 1:1 and 1:200. The epitaxial film is deposited into the predetermined regions of the substrate wherein the substrate has a temperature between about 350° C. and about 900° C. when the epitaxial film is being deposited. Alternatively, the substrate has a temperature between about 500° C. and about 800° C. when the epitaxial film is being deposited.

In another embodiment, a transistor is formed over a substrate having a gate electrode overlying a gate oxide, wherein the transistor is electrically isolated by a plurality of field oxide regions. Oxide spacers are formed adjacent to the gate electrode. Source and drain regions are formed in the substrate adjacent to the gate electrode. An epitaxial film forming process gas and a carrier gas are introduced over the substrate. The epitaxial film forming process gas and the carrier have a flow ratio between 1:1 and 1:200. And, the epitaxial film is deposited over regions of the substrate that are not covered by the gate electrode and the oxide spacers wherein the substrate has a temperature between about 350° C. and about 900° C. when the epitaxial film is being deposited. Alternatively, the substrate has a temperature between about 500° C. and about 800° C. when the epitaxial film is being deposited.

In another embodiment, a processing system that is used to form a substantially facet-free epitaxial film is disclosed. The processing system comprises a single wafer deposition chamber having a susceptor to hold a substrate during a deposition process. The single wafer deposition chamber further comprises a controller for controlling the chamber. A machine-readable medium is coupled to the controller. The machine-readable medium has a memory that stores a set of instructions. The set of instructions controls operations of the deposition process, controls selective deposition of an epitaxial film on a region of the substrate, maintains temperature at the substrate to be between 350° C. and 900° C., or alternatively, between 500° C. and 800° C., introduces an epitaxial film forming process gas and a carrier gas into the single wafer deposition chamber to deposit the epitaxial film into the region, and maintains a flow ratio for the epitaxial film forming process gas and the carrier gas to be between 1:1 to 1:200 during the deposition of the film.

The exemplary embodiments of the present invention can be used to fabricate integrated circuits where selective epitaxial film is needed. The epitaxial films formed using the exemplary methods and apparatuses of the present invention are substantially facet-free.

### BRIEF DESCRIPTION OF THE DRAWINGS

The present invention is illustrated by way of example and not limitation in the figures of the accompanying drawings, in which like references indicate similar elements and in which:

FIG. 1 illustrates an exemplary integrated circuit that uses a selectively deposited epitaxial film;

FIG. 2A-2B illustrate the difference between an epitaxial film having facets and an epitaxial film that is substantially facet-free;

FIG. 3 illustrates an exemplary method of selectively depositing an epitaxial film;

FIG. 4 illustrates an exemplary method of selectively depositing an epitaxial silicon film;

FIGS. 5A-5E illustrate an exemplary integrated circuit that incorporates some exemplary methods of selectively depositing an epitaxial silicon film in accordance with some embodiments of the present invention;

FIG. 6 illustrates an exemplary method of making an integrated circuit in accordance to some embodiments of the present invention; and

FIG. 7 illustrates an exemplary reactor chamber that can be utilized to selectively deposit a substantially facet-free epitaxial film in accordance with some embodiments of the present invention.

### DETAILED DESCRIPTION OF THE PRESENT INVENTION

The present invention describes methods and apparatuses for selectively deposing an epitaxial film that is substantially facet-free. In the following description numerous specific details are set forth in order to provide a thorough understanding of the present invention. One skilled in the art will appreciate that these specific details are not necessary in order to practice the present invention. In other instances, well known equipment features and processes have not been set forth in detail in order to not unnecessarily obscure the present invention.

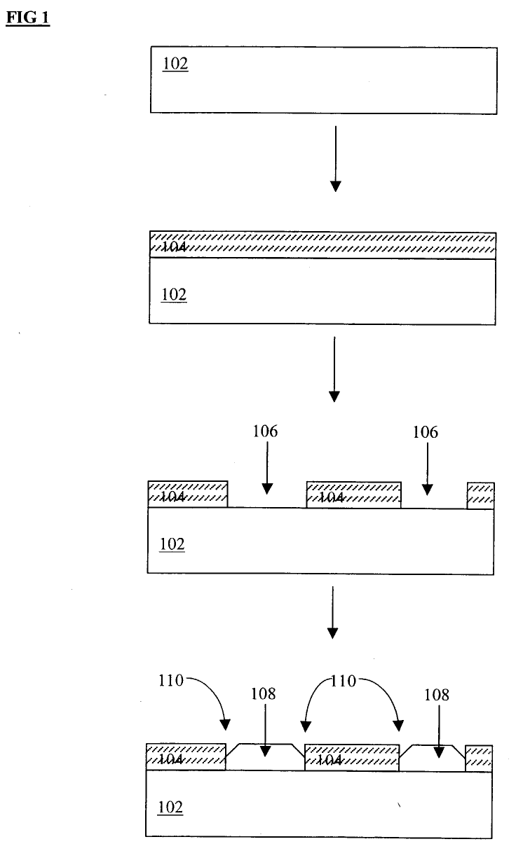

As mentioned above, faceting is the formation of another growth plane at a different angle from the major surface of the epitaxial silicon regions and often, at the sides of the regions that meet the wall of the structures already formed on the substrate. See for example, facets 110 illustrated in FIG. 1. Thus, the plane of the facet is along a different crystallographic plane than the major surface of the epitaxial film or region.

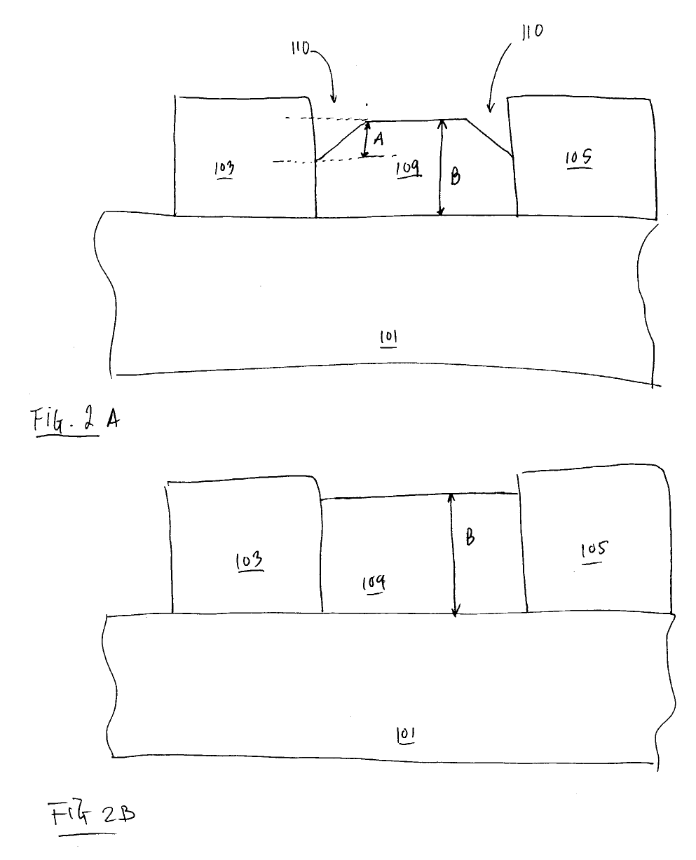

FIGS. 2A-2B illustrate what is referred to as “substantially facet-free.” In FIG. 2A, a substrate 101 includes a structure 103 and a structure 105 formed thereon. An epitaxial film 109 is selectively deposited on the substrate 101 wherein this figure further illustrates that the epitaxial film 109 has facets 10. The epitaxial film 109 has a maximum thickness (or height) “B” across the film whereas the facet 110 has a maximum thickness (or height) “A.” The ratio of the height A over the height B indicates the percentage of the faceting that the epitaxial film 109 contains. For example, if the height B is about 100 and the height A is about 50, the percentage of faceting is about 50% (A/B=50/100). In a substantially facet-free case, the height A is near zero and the faceting percentage is about 0%. For example, as shown in FIG. 2B, the epitaxial film 109 does not have any facet. When the height A is substantially equal zero, the epitaxial film is substantially facet-free. Substantially facet-free also refers to a percentage of faceting of less than 30%. Thus, any faceting percentage less than 30% or ideally, less than 10% is considered substantially facet-free for the purpose of this disclosure.

Epitaxial silicon films formed in according to some of the embodiments can be substantially facet-free (less than 30% faceting) or can be facet-free (0% faceting).

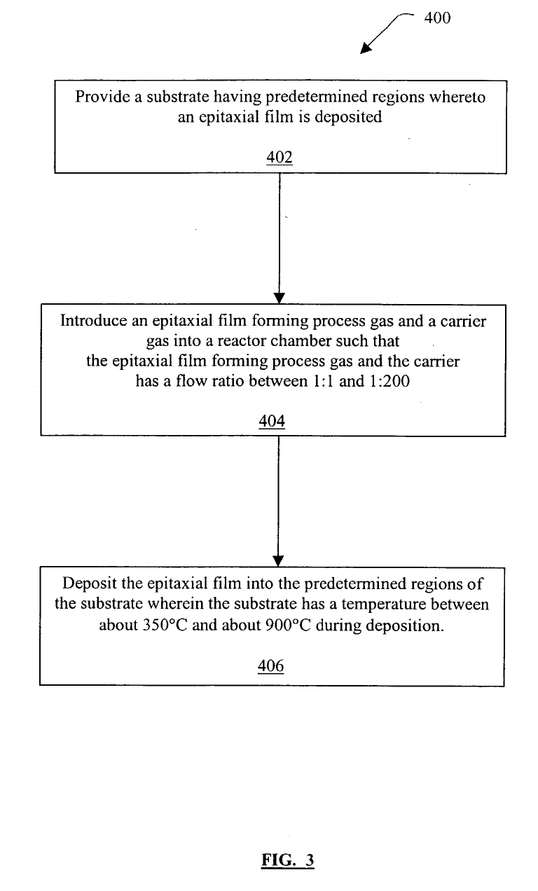

FIG. 3 illustrates an exemplary method 400 of selectively deposing an epitaxial film that is substantially facet-free. In one embodiment, an epitaxial film is referred to as a single crystalline semiconductor film. An epitaxial film can be a silicon film, germanium film, silicon-germanium film, silicon alloy film, germanium alloy film, or other types of semiconductor film. At operation 402, a substrate with predetermined regions whereto the epitaxial film is deposited is provided. In one embodiment, the substrate is a silicon wafer. In other embodiments, the substrate is other types of semiconductor material, for example, silicon-germanium wafer. The substrate includes structures (or patterns) already formed on the surface of the substrate. The structures can be semiconductor devices (e.g., a transistor) that can be fabricated on a silicon (or other semiconductor) wafer. The substrate has regions that are not covered by these structures. These regions are referred to as “predetermined regions.” In one embodiment, the epitaxial film (or epitaxial regions) is selectively deposited into the predetermined regions. In one embodiment, the epitaxial film is deposited only over silicon surface, silicon germanium surface and not on a dielectric surface or other insulation surface.

In one embodiment, prior to the deposition of the epitaxial film, the predetermined regions are etched to remove any residual surface damage that may have occurred during the fabrication process of the structures or patterns. A conventional method such as reactive ion etching can be used to remove any residual damages. In one embodiment, the etching to remove the residual damage is done by subjecting the substrate in a dilute mixture of an etchant containing HF and H₂O in HNO₃.

At operation 404, an epitaxial film forming process gas and a carrier gas are introduced into a reactor chamber, an example of which is described below in reference to FIG. 7. The epitaxial film forming process gas includes at least a silicon source gas and a chlorine source gas and optionally, a dopant source gas. The epitaxial film forming process gas may also be introduced into the reactor chamber together with the carrier gas. Generally, the epitaxial film forming process gas does not include a cleaning gas that is used to clean the reactor chamber after a deposition step. The carrier gas can be a hydrogen gas, an argon gas, a nitrogen gas, a helium gas, or other suitable dilution gas. The epitaxial film forming process gas and the carrier gas have a flow ratio between 1:1 and 1:200. Alternatively, the epitaxial film forming process gas and the carrier gas have a flow ratio between 1:10 and 1:90.

In one embodiment, the epitaxial film forming process gas includes at least a silicon source gas and a chlorine source gas (e.g., HCl), which enable the selective deposition of an epitaxial silicon film. The process gas may vary depending on the type of epitaxial film to be formed or deposited. For example, to form an epitaxial germanium film, a germanium source gas is used instead of the silicon source gas. Alternatively, to form an epitaxial silicon-germanium film, both the germanium source gas and the silicon source gas are used. The process gas may also include a dopant source gas (e.g., phosphorous, boron, antimony or arsenic) in the event that the epitaxial film is to be doped in situ. And, the dopant source gas may also be introduced with a carrier gas in some embodiments. Doping the epitaxial film creates a desired conductivity and resistivity for the epitaxial film.

Therefore, the epitaxial film forming process gas may include a chlorine source gas and at least one of a silicon source gas, a germanium source gas, a dopant source gas, and other reactive gas necessary to form the epitaxial film (doped or not doped). In most embodiments, the ratio of the epitaxial film forming process gas (e.g., a silicon source gas or a germanium source gas) and the chlorine source gas is about 1:1 to 100:1, the film forming gas to the chlorine source gas respectively. Thus, for example, in an embodiment where the process gas includes a silicon source gas and a chlorine source gas, the silicon source gas and the chlorine source gas have a flow ratio between 1:1 and 100:1. In another embodiment, the silicon source gas and the chlorine source gas have a flow ratio between 1:1 and 10:1. In one embodiment, the amount of the chlorine source gas is kept smaller than the amount of silicon source gas. Alternatively, the chlorine source gas is about equal to or less than the silicon source gas in the reactor chamber.

In one embodiment, the silicon source gas may be selected from a group consisting of monosilane (SiH₄), disilane (Si₂H₆), dichlorosilane (SiCl₂H₂), trichlorosilane (SiCl₃H), tetrachlorosilane (SiCl₄), and hexachlorodisilane (Si₂Cl₆). In one embodiment, the germanium source gas is germane (GeH₄). And, in one embodiment, the carrier gas is a hydrogen gas (H₂) or other suitable dilution gas such as argon (Ar), helium (He), and nitrogen (N₂).

At operation 406, the epitaxial film is deposited into the predetermined regions on the substrate. The substrate is heated up to a temperature between about 350° C. and 900° C. during the deposition of the epitaxial film. In another embodiment, the substrate is heated up to a temperature between about 700° C. and 850° C. during the deposition of the epitaxial film. Maintaining the temperature low, e.g., below 900° C. is necessary to prevent diffusion of dopants that may have already been implanted into the substrate or other structures or patterns on the substrate.

In one embodiment, the epitaxial film is formed at a pressure that is below atmospheric pressure. The epitaxial film may be formed at a pressure at about 760 Torr or below 760 Torr. For a blanket deposition of the epitaxial film, atmospheric pressure condition can be used. For a more selective and/or controlled deposition of the epitaxial film, a reduced pressure condition is used. In one embodiment, the epitaxial film is formed at a pressure between 10 Torr and 100 Torr. In another embodiment, the epitaxial film is formed at a pressure below 30 Torr or ideally, at a pressure between 10-20 Torr. In one embodiment, the epitaxial film of about 300-1000 angstroms is deposited in a period of about 1-3 minutes.

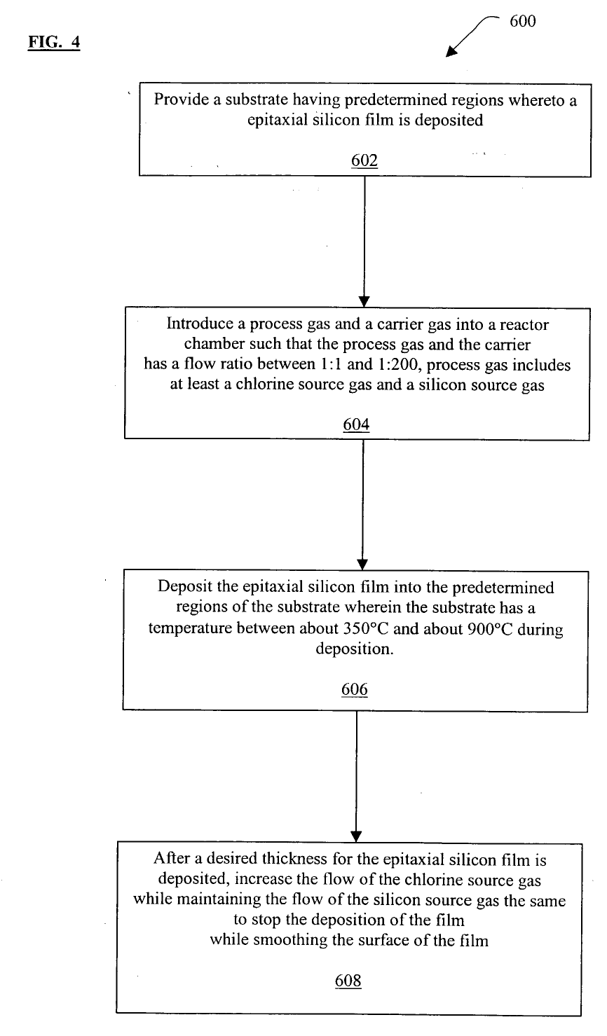

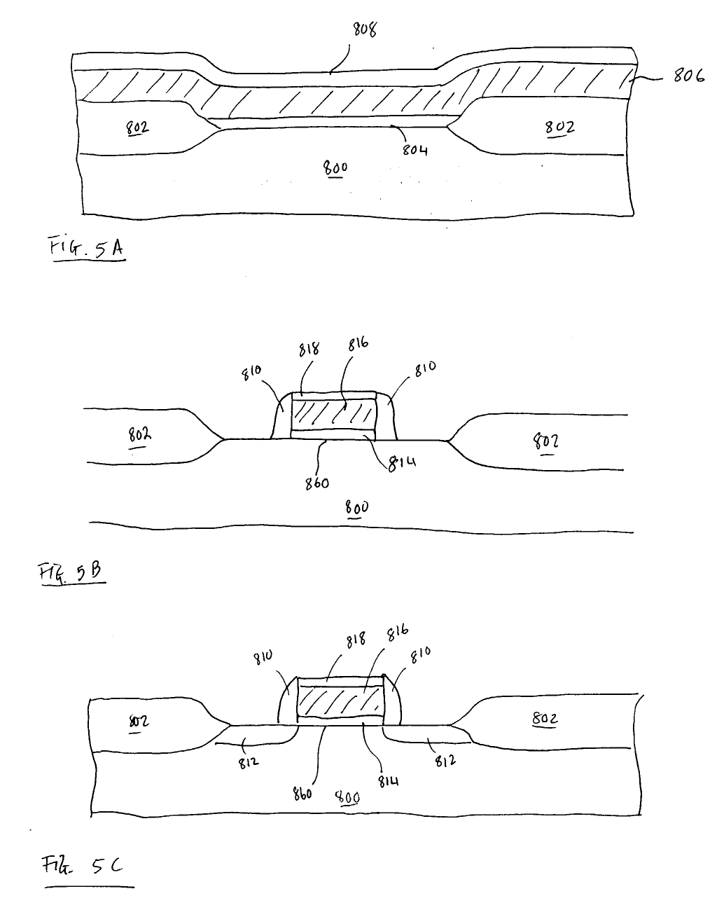

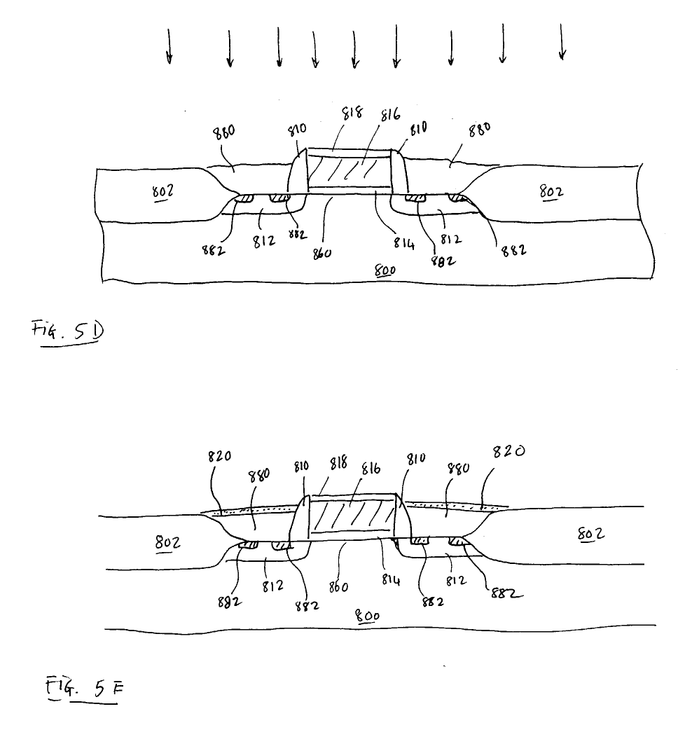

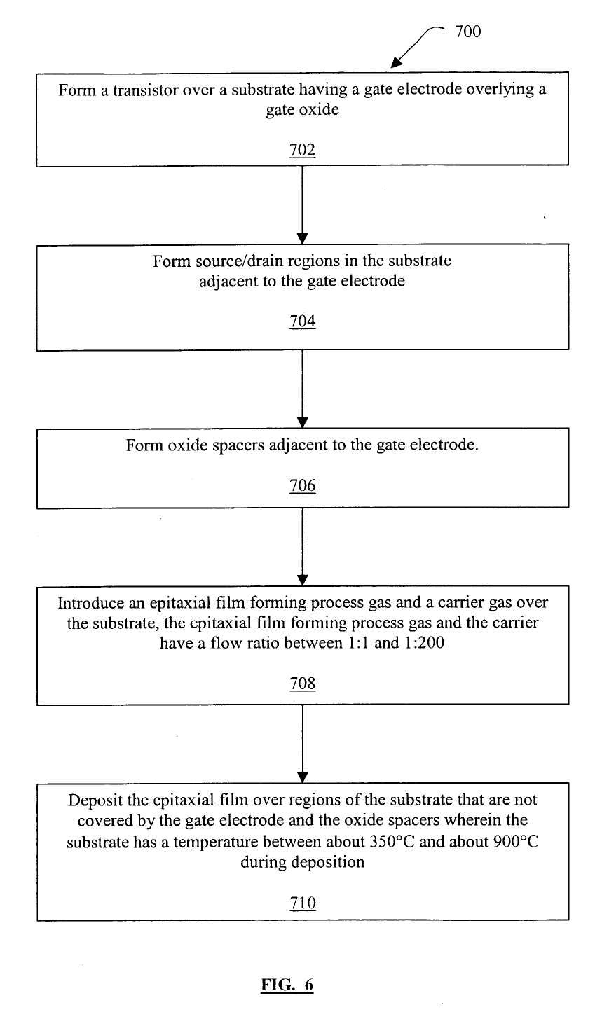

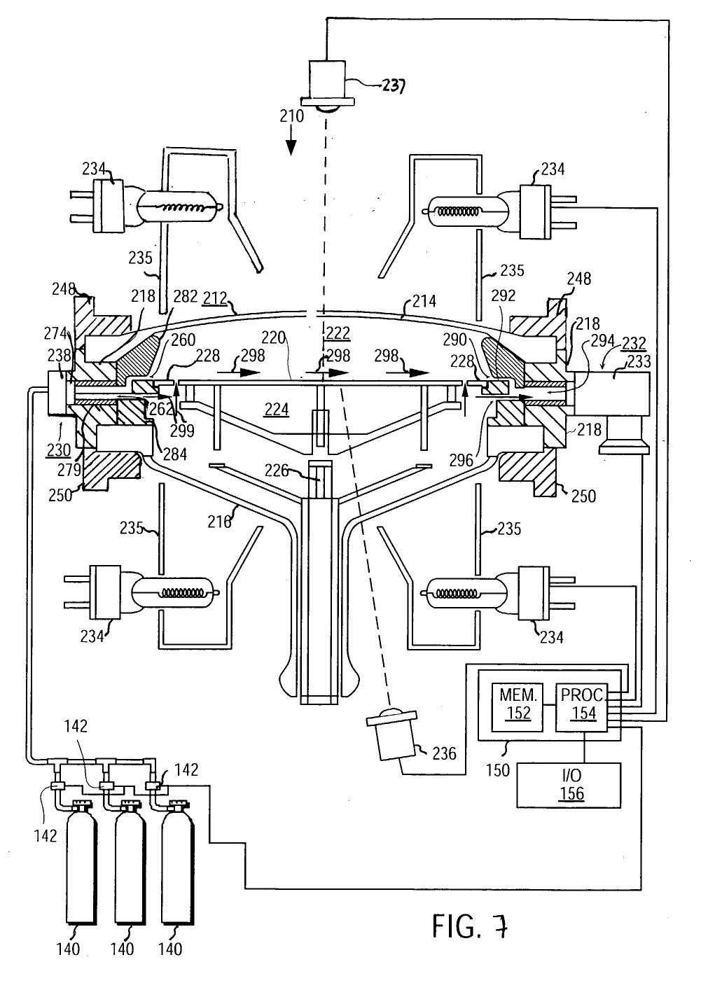

FIG. 4 illustrates an exemplary method 600 of selectively deposing an epitaxial silicon film that is substantially facet-free. At operation 602, a substrate with predetermined regions whereto the epitaxial silicon film is deposited is provided. In one embodiment, the substrate is a monocrystalline silicon wafer. The substrate includes structures (or patterns) already formed on the surface of the substrate. The structures can be semiconductor devices (e.g., a transistor) that can be fabricated on a silicon (or other semiconductor) wafer. The substrate has regions that are not covered by these structures. These regions are referred to as “predetermined regions.” In one embodiment, the epitaxial silicon film (or epitaxial regions) is selectively deposited into the predetermined regions.

Similar to as described in method 400, in the method 600, prior to the deposition of the epitaxial film, the predetermined regions can be treated with etchant containing HF and H₂O in HNO₃ to remove any residual surface damage that may have occurred during the fabrication process of the structures or patterns. At operation 604, an epitaxial silicon film forming process gas and a carrier gas are introduced into a reactor chamber, an example of which is illustrated in FIG. 7. The epitaxial silicon film forming process gas and the carrier gas have a flow ratio between 1:1 and 1:200. Alternatively, the epitaxial silicon film forming process gas and the carrier gas have a flow ratio between 1:10 and 1:90.

In one embodiment, the epitaxial silicon film forming process gas includes at least a silicon source gas and a chlorine source gas (e.g., HCl). The process gas may also include a dopant source gas (e.g., phosphorous, boron, antimony or arsenic) in the event that the epitaxial silicon film is to be doped in situ. Doping the epitaxial silicon film creates a desired conductivity and resistivity for the epitaxial silicon film. In one embodiment, the ratio of the silicon source gas and the chlorine source gas is about 1:1 to 100:1. In another embodiment, the silicon source gas and the chlorine source gas have a flow ratio between 1:1 and 10:1.

In one embodiment, the silicon source gas (e.g., SiCl₂H₂) is maintained at a flow rate approximately between 100 sccm and 800 sccm, and in another embodiment, approximately between 200 sccm and 500 sccm. In one embodiment, the chlorine source gas (e.g., HCl) is maintained at a flow rate approximately between 10 sccm and 500 sccm, and in another embodiment, approximately between 500 sccm and 300 sccm. In one embodiment, the carrier gas (e.g., H₂, Ar, He, and N₂) is maintained at a flow rate approximately between 5000 sccm and 100,000 sccm, and in another embodiment, approximately between 5000 sccm and 50,000 sccm. In some embodiment, using the flow rate, flow ratio, temperature, and pressure parameters described above, it takes about 1-3 minutes to deposit an epitaxial silicon film of about 300-1000 angstrom. It is to be noted that the various flow rates mentioned for the exemplary embodiments may be changed according to the size (or volume) of the reactor chamber that the films are formed. For example, the flow rates listed above are for the reactor chamber described in FIG. 7. In one embodiment, the flow rates listed above are for a reactor chamber that has a process volume of about 3-4 litters.

In one embodiment, the silicon source gas may be selected from a group consisting of SiH₄, Si₂H₆, SiCl₂H₂, SiCl₃H, SiCl₄, and Si₂Cl₆. And, in one embodiment, the carrier gas is a hydrogen gas (H₂) or other suitable dilution gas (e.g., Ar, He, and N₂).

At operation 606, the epitaxial silicon film is deposited into the predetermined regions on the substrate. The substrate is heated up to a temperature between about 350° C. and 900° C. during the deposition of the epitaxial silicon film. In another embodiment, the substrate is heated up to a temperature between about 700° C. and 850° C. during the deposition of the epitaxial silicon film.

In one embodiment, the epitaxial film is formed at a pressure that is below atmospheric pressure. The epitaxial film may be formed at a pressure at about 760 Torr or below 760 Torr. Alternatively, the epitaxial film may be formed at a pressure below 30 Torr or ideally between 10-20 Torr. In yet another embodiment, the epitaxial film is formed at a pressure between 10-100 Torr.

Operation 608 is optional. At operation 608, the epitaxial film is smoothed. In some embodiments, to smooth out the surface of the epitaxial silicon film, after a desired thickness (e.g., 300-1000 angstrom) is deposited, the flow ratio of the silicon source gas and the chlorine source gas is modified to stop the deposition while allowing smoothing of the epitaxial film surface. To do this, the flow rate of the silicon source gas is maintained the same while the flow rate of the chlorine source gas is increased. For example, if during the deposition, the flow rate for silicon source gas is at about 300 sccm and the flow rate for the chlorine source gas is about 100 sccm, then during the operation 608, the flow rate for silicon source gas is maintained at about 300 sccm and the flow rate for the chlorine source gas may be increased to about 150 sccm. The chlorine source is increased to an amount that prevents further deposition of the epitaxial silicon film while allowing smoothing out of the surface of the epitaxial film that is already deposited. In one embodiment the pressure may be decreased slightly, for example, from 15 Torr for during deposition to 10 Torr for during smoothing to ensure that no substantial deposition occurs during smoothing. In another embodiment, the carrier gas may also be decreased, for example, from 30,000 sccm for during deposition to 5,000 sccm for during smoothing. Decreasing the carrier gas increases the process gas for the deposition. In one embodiment, the smoothing of the epitaxial film occurs for about 10-50 seconds.

FIGS. 5A-5E illustrate an exemplary integrated circuit that can be formed using some embodiments of the present invention. FIG. 5A illustrates a portion of a wafer, in cross-section, which has a surface at which isolation structures and devices in adjacent active areas are to be formed. As shown in FIG. 5A, a monocrystalline silicon substrate 800 is provided. The silicon substrate 800 may be p-doped or n-doped silicon depending upon the location in the wafer where the isolation and active devices are to be formed. In one embodiment, field oxide regions 802 are formed on various portions of the substrate 800 to isolate the active areas where devices will be formed. After various conventional processing steps have been performed, a gate oxide layer 804 is formed over the silicon substrate 800. In one embodiment, the gate oxide layer 804 has a thickness of approximately 20 to 300 angstroms. Next, a polysilicon layer 806 is formed over the gate oxide layer 804 and the field oxide regions 802. In one embodiment, the polysilicon layer 806 has a thickness of between approximately 1000-6000 angstroms. In one embodiment, a dielectric capping layer 808 made of material such as oxide or nitride is then formed over the polysilicon layer 806. In one embodiment, the dielectric capping layer 808 has a thickness of between approximately 1000 to 2000 angstroms.

FIG. 5B illustrates that the gate oxide 804, the polysilicon layer 806, and the oxide capping layer 808 are then patterned and etched using conventional methods to form the gate of a transistors 860. The transistor 806 comprises a gate oxide 814, a polysilicon gate electrode 816, and a dielectric cap 818. In one embodiment, the gate electrode 816 may comprise a suicide layer (not shown) overlying the polysilicon gate electrode 816. The silicide layer will help to reduce the sheet resistance of the polysilicon gate electrode 816.

FIG. 5C illustrates that lightly doped drain and source regions 812 of the transistor 860 are formed into the substrate 800. The source/drain regions 812 are typically formed by a phosphorous implant in the silicon substrate 800 adjacent to the edge of the polysilicon gate electrode 816. In one embodiment, sidewall spacers 810 are formed along the edge of the gate of the transistor 860. The sidewall spacers 810 can be made of silicon oxide, nitride, oxynitride, or other dielectric material. In the embodiment where the transistor 860 includes the dielectric cap 818, the sidewall spacers 810 will also form along the side of the dielectric cap 818.

As illustrated in FIG. 5D, regions of epitaxial silicon 880 are selectively grown over the source/drain regions 812. It is to be appreciated that the epitaxial silicon film collectively refers to epitaxial silicon regions 880 that are selectively deposited across the surface of the substrate 800. In one embodiment, the regions of epitaxial silicon 880 are used to form elevated source/drain regions 882. In this embodiment, the epitaxial silicon film are formed or deposited over the source/drain regions 812 followed by implantation in order for the elevated source/drain regions 882 to be formed. In one embodiment, the substrate 800 with the transistor 860 is placed inside a reactor chamber, which could be a single wafer deposition chamber (see for example, FIG. 7). An epitaxial film can be formed using the exemplary methods described above. In one embodiment, an epitaxial silicon film forming process gas and a carrier gas having a flow ratio between 1:1 and 1:200 are introduced. The epitaxial film forming process gas includes at least a silicon source gas (e.g., SiH₄, Si₂H₆, SiCl₂H₂, SiCl₃H, SiCl₄, and Si₂Cl₆) and a chlorine source gas (e.g., HCl). The process gas may also include a dopant source gas (e.g., phosphorous, boron, antimony or arsenic) in the event that the epitaxial silicon film 880 is to be doped in situ. The substrate is maintained at a temperature between about 350° C. and 900° C. during the deposition of the epitaxial silicon film 880.

In one embodiment, after a desired thickness for the epitaxial silicon film 880 is deposited, the flow of the HCl source gas is increased while the flow of the silicon source gas is maintained at the same rate (as the rate that is used for the deposition). This operation stops the deposition of the epitaxial film 880 while smoothing out the surface of the epitaxial film 880 as previously described. In one embodiment, the epitaxial silicon film 880 has a thickness substantially the same with the combination of the gate oxide 814 and the polysilicon gate electrode 816. The upper surface of the epitaxial silicon film 880 can be formed to a height above the silicon substrate 800 and substantially planar with an upper surface of the polysilicon gate electrode 816. In one embodiment, the epitaxial silicon film 880 is selectively deposited only on silicon surface and not on a dielectric surface or an oxide surface such as the dielectric cap layer 818 or the field oxide regions 802. In one embodiment, the epitaxial silicon film 880 is substantially facet-free (less than 30% faceting) or is facet-free (0% faceting).

In one embodiment, the epitaxial silicon film 880 is implanted with an N+ or P+ dopant as shown by the arrows in FIG. 5D to form the elevated source/drain regions 882. In this embodiment, the epitaxial silicon film 880 needs to be implanted with sufficient energy and dose to achieve continuity with the doped source/drain regions in the substrate 800 as is well known in the art. The doping of the epitaxial silicon film 880 creates the heavily doped source/drain regions 882 in the epitaxial silicon film 880. In some embodiments, the heavily doped source/drain regions 882 have the same depth as the lightly doped source/drain regions 812 or alternatively, the heavily doped source/drain regions may have more or less junction depth.

As illustrated in FIG. 5E, a metal layer, such as a refractory metal layer, is formed over the integrated circuit. The substrate 800 is heated to allow the metal to react with the underlying epitaxial silicon film 880 to form a silicide 820. The silicide 820 will lower the resistivity of the epitaxial silicon film 880 that is used to form the raised source and drain regions 882. The raised source/drain epitaxial regions 882 prevent any undesired amount of the substrate silicon from being consumed. The possibility of junction leakage and punchthrough between the lightly doped source/drain regions 812 are substantially reduced with the epitaxial silicon film 880. The raised source/drain regions 882 formed from the epitaxial silicon film 880 prevent any lateral diffusion of suicide in the source/drain regions 812.

It is to be understood that the integrated circuit illustrated in FIG. 5A-5E is only an exemplary application of the exemplary methods of selectively depositing a substantially facet-free epitaxial film. Other possible application includes fabrications of isolated regions for semiconductor devices, heterojunctions bipolar transistor, ultra shallow junctions, or devices where selective deposition of an epitaxial film into a predetermined region is needed.

FIG. 6 illustrates an exemplary method 700 of forming an integrated circuit such as the one described in FIGS. 5A-5E. At operation 702, a transistor is formed over a substrate having a gate electrode overlying a gate oxide. At operation 740, source/drain regions are formed in the substrate adjacent the gate electrode. At operation 706, oxide spacers are formed adjacent the gate electrode.

At operation 708, an epitaxial silicon film forming process gas and a carrier gas are introduced into a reactor chamber. In one embodiment, the epitaxial silicon film forming process gas and the carrier gas have a flow ratio between 1:1 and 1:200. In another embodiment, the epitaxial silicon film forming process gas and the carrier gas have a flow ratio between 1:10 and 1:90. In one embodiment, the epitaxial film forming process gas includes at least a silicon source gas and a chlorine source gas (e.g., HCl), which enable the deposition of an epitaxial silicon film. The process gas may also include a dopant source gas (e.g., phosphorous, boron, antimony or arsenic) in the event that the epitaxial film is to be doped in situ. In one embodiment, the silicon source gas may be selected from a group consisting of SiH₄, Si₂H₆, SiCl₂H₂, SiCl₃H, SiCl₄, and Si₂Cl₆. And, in one embodiment, the carrier gas is an H₂ gas or other suitable dilution gas. In one embodiment, the silicon source gas and the chlorine source gas have a flow ratio between 1:1 and 100:1. In another embodiment, the silicon source gas and the chlorine source gas have a flow ratio between 1:1 and 10:1.

At operation 710, the epitaxial silicon film is deposited over the predetermined regions on the substrate, for example, regions of the substrate that are not covered by the gate electrode and the oxide spacers. The substrate is heated up to a temperature between about 350° C. and 900° C. during the deposition of the epitaxial film. The reactor chamber is maintained at a pressure below atmospheric pressure (e.g., below 760 Torr) during the deposition. Alternatively, the pressure may be below 30 Torr.

FIG. 7 illustrates an exemplary reactor chamber that can be used for selectively depositing an epitaxial film such as those previously described. It is to be understood that other conventional reaction chamber typically used for chemical vapor deposition process can also be used. FIG. 7 illustrates a reactor chamber 210, which is a deposition reactor that can be used to selectively deposit the epitaxial film. The reactor chamber 210 comprises a deposition chamber 212 having an upper dome 214, a lower dome 216, and a sidewall 218 between the upper and lower domes 214 and 216. Cooling fluid (not shown) is circulated through sidewall 218 in order to cool the sidewall 218. An upper liner 282 and a lower liner 284 are mounted against the inside surface of the sidewall 218. The upper and lower domes 214 and 216 are made of a transparent material to allow heating light to pass through into the chamber 212.

Within the chamber 212 is a flat, circular susceptor 220 for supporting a wafer (or a semiconductor substrate) in a horizontal position. The susceptor 220 is sometimes referred to as a substrate holder. The susceptor 220 extends transversely across the chamber 212 at the sidewall 218 to divide the chamber 212 into an upper portion 222 above the susceptor 220 and a lower portion 224 below the susceptor 220. The susceptor 220 is mounted on a shaft 226 which extends perpendicularly downwardly from the center of the bottom of the susceptor 220. The shaft 226 is connected to a motor (not shown) which rotates the shaft 226 in order to rotate the susceptor 220. In one embodiment, the wafer supported by the susceptor 220 is rotated throughout the deposition process. An annular preheat ring 228 is connected at its outer periphery to the inside periphery of the lower liner 284 and extends around the susceptor 220. The pre-heat ring 228 is in the same plane as the susceptor 220.

An inlet manifold 230 is positioned in the side of the chamber 212 and is adapted to admit gas from a source of gas or gases, such as tanks 140, into the chamber 212. An outlet port 232 is positioned in the side of chamber 212 diagonally opposite the inlet manifold 230 and is adapted to exhaust gases from the deposition chamber 212.

A plurality of high intensity lamps 234 are mounted around the chamber 212 and direct their light through the upper and lower domes 214 and 216 onto the susceptor 220 (and the preheat ring 228) to heat the susceptor 220 (and the preheat ring 228). Heating the susceptor 220 in turns heat the substrate or the wafer that the susceptor 220 supports. The susceptor 220 and the preheat ring 228 are made of a material, such as silicon carbide, coated graphite which is opaque to the radiation emitted from the lamps 234 so that they can be heated by radiation from the lamps 234. The upper and lower domes 214 and 216 are made of a material which is transparent to the light of the lamps 234, such as clear quartz. The upper and lower domes 214 and 216 are generally made of quartz because quartz is transparent to light of both visible and IR frequencies. Quartz exhibits a relatively high structural strength; and it is chemically stable in the process environment of the deposition chamber 212. Although lamps are the preferred elements for heating wafers in deposition chamber 212, other methods may be used such as resistance heaters and Radio Frequency inductive heaters.

An infrared temperature sensor 236 such as a pyrometer is mounted below the lower dome 216 and faces the bottom surface of the susceptor 220 through the lower dome 216. The temperature sensor 236 is used to monitor the temperature of the susceptor 220 by receiving infrared radiation emitted from the susceptor 220 when the susceptor 220 is heated. A temperature sensor 237 for measuring the temperature of a wafer may also be included if desired.

An upper clamping ring 248 extends around the periphery of the outer surface of the upper domes 214. A lower clamping ring 250 extends around the periphery of the outer surface of the lower dome 216. The upper and lower clamping rings are secured together so as to clamp the upper and lower domes 214 and 216 to the sidewall 218.

The gas inlet manifold 230 included in the apparatus 210 feeds process gas (or gases) and carrier gas into the chamber 212. The gas inlet manifold 230 includes a connector cap 238, a baffle 274, and an insert plate 279 positioned within the sidewall 218. Additionally, the connector cap 238, the baffle 274, and the insert plate 279 are positioned within a passage 260 formed between upper liner 282 and lower liner 284. The passage 260 is connected to the upper portion 222 of chamber 212. Process gas (or gases) are introduced into the chamber 212 from the connector cap 238, the gas or gases are then flown through the baffle 274, through the insert plate 279, and through the passage 260 and then into the upper portion 222 of chamber 212.

The reactor chamber 210 also includes an independent gas inlet 262 for feeding a purge gas, such as hydrogen (H₂) or Nitrogen (N₂), into the lower portion 224 of deposition chamber 212. As shown in FIG. 7, the purge gas inlet 262 can be integrated into gas inlet manifold 230, if desired, as long as a physically separate and distinct passage 262 through the baffle 274, the insert plate 279, and the lower liner 284 is provided for the purge gas, so that the purge gas can be controlled and directed independent of the process gas. The purge gas inlet 262 need not be integrated or positioned along with deposition gas inlet manifold 230, and can, for example, be positioned on the reactor 210 at an angle of 90° from a deposition gas inlet manifold 230.

As mentioned, the reactor chamber 210 also includes a gas outlet 232. The gas outlet 232 includes an exhaust passage 290, which extends from the upper chamber portion 222 to the outside diameter of sidewall 218. The exhaust passage 290 includes an upper passage 292 formed between the upper liner 282 and the lower liner 284 and which extends between the upper chamber portion 222 and the inner diameter of sidewall 218. Additionally, the exhaust passage 290 includes an exhaust channel 294 formed within the insert plate 279 positioned within sidewall 218. A vacuum source, such as a pump (not shown) for creating low or reduced pressure in the chamber 212 is coupled to the exhaust channel 294 on the exterior of sidewall 218 by an outlet pipe 233. The process gas (or gases) and the carrier gas fed into the upper chamber portion 222 are exhausted through the upper passage 292, through the exhaust channel 294 and into the outlet pipe 233.

The gas outlet 232 also includes a vent 296, which extends from the lower chamber portion 224 through lower liner 284 to the exhaust passage 290. The vent 296 preferably intersects the upper passage 292 through the exhaust passage 290 as shown in FIG. 7. The purge gas is exhausted from the lower chamber portion 224 through the vent 296, through a portion of the upper chamber passage 292, through the exhaust channel 294, and into the outlet pipe 233. The vent 296 allows for the direct exhausting of the purge gas from the lower chamber portion to the exhaust passage 290.

According to some exemplary embodiment of the present invention, the process gas or gases 298 are fed into the upper chamber portion 222 from gas inlet manifold 230. In some exemplary embodiments, the process gas is defined as the gas or gas mixture which acts to remove, treat, or deposit a film on a wafer or a substrate that is placed in chamber 212. In one embodiment, the process gas comprises a chlorine source gas and a silicon source gas. In this embodiment, the chlorine source gas and the silicon source gas are used to selectively form or deposit an epitaxial silicon film according to some exemplary embodiments of the present invention.

In one exemplary embodiment, while the process gas is fed into the upper chamber portion 222, an inert purge gas or gases 299 are fed independently into the lower chamber portion 224. Purging the chamber 212 with the purge gas 299 prevents an unwanted reaction at the bottom side of the chamber 212 or the bottom side of the susceptor 220.

In one exemplary embodiment, the reactor chamber 210 shown in FIG. 7 is a single wafer reactor that is also “cold wall” reactor. The sidewall 218 and upper and lower liners 282 and 284, respectively, are at a substantially lower temperature than the preheat ring 228 and the susceptor 220 (and a wafer placed thereon) during processing. For example, when deposition process occurs at a temperature of about 800° C. to 900° C., the susceptor and the wafer are heated to a temperature between 800° C. to 900° C. while the sidewall and the liners are at a temperature of about 400-600° C. The sidewall 218 and liners 282 and 284 are at a cooler temperature because they do not receive direct irradiation from lamps 234 due to reflectors 235, and because cooling fluid is circulated through the sidewall 218.

The reactor chamber 210 has a process volume, which is the space above the susceptor 220, of about 3-4 litters. The reactor chamber 210 also has a “dead volume,” which is the space below the susceptor 220, of about 7-8 litters. As previously mentioned, the flow rates listed in the various embodiments are for the volume size of the reactor chamber 210. The flow rates can be varied according to the different sizes of different reactor chamber without deviating from the scope of the embodiments.

In another exemplary embodiment, the processing reactor chamber 210 shown in FIG. 7 includes a system controller 150 that controls the reactor chamber 210. The system controller 150 controls various operations of the reactor chamber 210 such as controlling gas flows into the chamber 212, controlling the substrate's temperature, controlling the susceptor 220's temperature, and controlling the chamber's pressure. In one exemplary embodiment, the system controller 150 includes a machine-readable medium 152 such as a hard disk drive (indicated in FIG. 4 as “memory 152”) or a floppy disk drive. The system controller 150 also includes a processor 154. An input/output device 156 such as a keyboard, a mouse, a light pen, and a CRT monitor, is used to interface between a user the and the system controller 150.

In one exemplary embodiment, the system controller 150 controls all of the activities of the reactor chamber 210. The system controller executes system control software, which is a computer program stored in the machine-readable medium 152. Preferably, the machine-readable medium 152 is a hard disk drive, but the machine-readable medium 152 may also be other kinds of memory stored in other kinds of machine-readable media such as one stored on another memory device including, for example, a floppy disk or another appropriate drive. The computer program includes sets of instructions that dictate the timing, mixture of gases, chamber pressure, chamber temperature, lamp power levels, susceptor position, and other parameters of a particular process, for example, a selective deposition process.

The process for selectively depositing an epitaxial film in accordance with the exemplary embodiments of the present invention can be implemented using a computer program product, which is stored in the machine-readable medium 152 and, is executed by the processor 154. The computer program code can be written in any conventional computer readable programming language, such as, 68000 assembly language, C, C ++, Pascal, Fortran, or others. Also stored in the machine-readable medium 152 are process parameters such as the process gas flow rates (e.g., silicon source gas, HCl, and H₂ gas flow rates), the deposition temperatures and the pressure necessary to carry out the deposition in accordance with the exemplary embodiments of the present invention.

In one embodiment, the program code (which can be a set of instructions) controls selective deposition of an epitaxial film on a region of a substrate wherein the instructions maintain temperature at the substrate to be between 350° C. and 900° C. for the film deposition. The instructions further introduce an epitaxial film forming process gas and a carrier gas into a particular process chamber to deposit an epitaxial film into the region. The instructions also maintain a flow ratio for the epitaxial film forming process gas and the carrier gas to be between 1:1 to 1:200.

In one embodiment, the reactor chamber 210 is integrated into a cluster tool system that may comprise several other process chambers or other reactor chambers. A system controller similar to the system controller 150 can be included. This system controller can execute programs that will control the operations of the cluster tool including the reactor chamber 210.

While certain exemplary embodiments have been described and shown in the accompanying drawings, it is to be understood that such embodiments are merely illustrative and not restrictive of the current invention, and that this invention is not restricted to the specific constructions and arrangements shown and described since modifications may occur to those ordinarily skilled in the art.

1. A method of selectively depositing an epitaxial film comprising:
providing a substrate having predetermined regions;
introducing an epitaxial film forming process gas and a carrier gas into a reactor chamber, said epitaxial film forming process gas and said carrier have a flow ratio between 1:1 and 1:200; and
depositing said epitaxial film into said regions wherein said substrate has a temperature between about 350° C. and about 900° C. when said epitaxial film is being deposited.

2. The method of claim 1 wherein said epitaxial film includes at least one of silicon, silicon alloy, germanium, germanium alloy, and silicon-germanium alloy.

3. The method of claim 1 wherein said epitaxial film includes silicon and wherein said epitaxial film forming process gas includes at least a chlorine source gas and a silicon source gas.

4. The method of claim 3 wherein said silicon source gas and said chlorine source gas have a flow ratio between 1:1 to 100:1.

5. The method of claim 3 further comprising:
after a desired thickness for said epitaxial film is deposited, increasing the flow of said chlorine source gas while maintaining the flow of said silicon source gas the same to stop the deposition of said epitaxial film while smoothing the surface of said epitaxial film.

6. The method of claim 1 wherein said epitaxial film includes germanium and wherein said epitaxial film forming process gas includes at least a chlorine source gas and a germanium source gas.

7. The method of claim 1 wherein said epitaxial film includes silicon and germanium and wherein said epitaxial film forming process gas includes at least a chlorine source gas, a silicon source gas, and a germanium source gas.

8. The method of claim 1 wherein said reactor chamber has a pressure below atmospheric pressure when said epitaxial film is being deposited.

9. The method of claim 1 wherein said reactor chamber is a single wafer deposition chamber.

10. The method of claim 1 wherein said process gas comprises a silicon source gas that is selected from a group consisting of monosilane, disilane, dichlorosilane, trichlorosilane, tetrachlorosilane, and hexachlorodisilane.

11. The method of claim 1 wherein said epitaxial film has a thickness less than 1000A and is substantially facet-free.

12. A method of forming an integrated circuit comprising:
forming a transistor over a substrate having a gate electrode overlying a gate oxide, wherein said transistor is electrically isolated by a plurality of field oxide regions;
forming a source and a drain regions in said substrate adjacent to said gate electrode;
forming oxide spacers adjacent to said gate electrode;
introducing an epitaxial film forming process gas and a carrier gas over said substrate, said epitaxial film forming process gas and said carrier have a flow ratio between 1:1 and 1:200; and
depositing said epitaxial film over regions of said substrate that are not covered by said gate electrode and said oxide spacers wherein said substrate has a temperature between about 350° C. and about 900° C. when said epitaxial film is being deposited.

13. The method of claim 12 wherein said epitaxial film includes silicon and wherein said epitaxial film forming process gas includes at least a chlorine source gas and a silicon source gas.

14. The method of claim 12 wherein said silicon source gas and said chlorine source gas have a flow ratio between 1:1 to 100:1.

15. The method of claim 14 further comprising:
after a desired thickness for said epitaxial film is deposited, increasing the flow of said chlorine source gas while maintaining the flow of said silicon source gas to stop the deposition of said epitaxial film and to smooth the surface of said epitaxial film.

16. The method of claim 1 wherein said epitaxial film includes at least one of silicon, silicon alloy, germanium, germanium alloy, and silicon-germanium alloy.

17. An integrated circuit comprising:
a semiconductor substrate having predetermined regions;
an epitaxial film selectively deposited in said regions, said epitaxial film being substantially facet-free.

18. The integrated circuit of claim 17 wherein said epitaxial film includes at least one of silicon, silicon alloy, germanium, germanium alloy, and silicon-germanium alloy.

19. The integrated circuit of claim 17 wherein said epitaxial film is formed with an epitaxial film forming process gas and a carrier gas in a reactor chamber wherein said epitaxial film forming process gas and said carrier having a flow ratio between 1:1 and 1:200.

20. A processing system comprising:
a single wafer deposition chamber having a susceptor to hold a substrate during a deposition process;
a controller for controlling said single wafer deposition chamber;
a machine-readable medium coupling to said controller, said machine-readable medium has a memory that stores a set of instructions that controls operations of said deposition process; and
wherein said set of instructions further controls selective deposition of an epitaxial film on a region of said substrate, wherein said set of instructions maintains temperature at said substrate to be between 350° C. and 900° C. and introduces an epitaxial film forming process gas and a carrier gas into said single wafer deposition chamber to deposit an epitaxial film into said region, and wherein said instructions maintains a flow ratio for said epitaxial film forming process gas and said carrier gas to be between 1:1 to 1:200.

21. The process system of claim 20 wherein said epitaxial film includes silicon, wherein said epitaxial film forming process gas includes at least a chlorine source gas and a silicon source gas, and wherein said instructions maintain a flow ratio for said silicon source gas and said chlorine source gas to be between 1:1 to 100:1.

22. The process system of claim 21 wherein said instructions increases the flow of said chlorine source gas while maintaining the flow of said silicon source gas to stop the deposition of said epitaxial film after a desired thickness for said epitaxial film is deposited to smooth the surface of said epitaxial film.

23. A processing system comprising:
a single wafer deposition chamber having a susceptor to hold a first substrate during a deposition process;
a controller for controlling said single wafer deposition chamber;
a machine-readable medium coupling to said controller, said machine-readable medium has a memory that stores a set of instructions that controls operations of said deposition process; and
wherein said set of instructions further controls selective deposition of an epitaxial film on a region of said substrate wherein said instructions maintains temperature at said substrate to be between 350° C. and 900° C. and introduces an epitaxial film forming process gas and a carrier gas into said single wafer deposition chamber to deposit an epitaxial film into said region, wherein said instructions maintains a flow ratio for said epitaxial film forming process gas and said carrier gas to be between 1:1 to 1:200.
